(19) United States
(12) Patent Application Publication
(10) Pub. No.: US 2014/0010377 A1
(43) Pub. Date: Jan. 9, 2014

(54) ELECTRONIC DEVICE AND METHOD OF ADJUSTING VOLUME IN TELECONFERENCE

(71) Applicant: HON HAI PRECISION INDUSTRY CO., LTD., New Taipei (TW)

(72) Inventors: CHUN-TANG HSU, New Taipei (TW); HSUEH-TSEN TSAI, New Taipei (TW); HSIAO-PING CHIU, New Taipei (TW)

(21) Appl. No.: 13/928,743

(22) Filed: Jun. 27, 2013

(30) Foreign Application Priority Data
Jul. 6, 2012 (TW) 101124474

(51) Int. Cl. H03G 7/00

(52) U.S. Cl. CPC H03G 7/00
USPC 381/57

(57) ABSTRACT

An electronic device is used in a teleconference. Each attendee location of the teleconference has at least one electronic device. The electronic device detects ambient noise and sets a volume range of a speaker of the electronic device according to the ambient noise. When an attendee location sends audio to the electronic device, a receiver of the electronic device receives the audio and analyzes volume parameter from the audio. When the volume parameter is in the volume range, the speaker outputs the audio directly. When the volume parameter is not in the volume range, the electronic device adjusts a digital sound value of the attendee location and outputs the audio with the adjusted digital sound value.

### BACKGROUND

1. Technical Field

Embodiments of the present disclosure relate to adjusting volume technology, and more particularly to an electronic device and a method of adjusting volume in a teleconference.

2. Description of related art

Teleconference is convenient for attendees who might be at remote locations. However, for some remote locations, because of ambient noise the sound volume may be too low and for other remote locations the sound volume may be too high. As such, the teleconference audio for some remote attendee may be unintelligible.

### BRIEF DESCRIPTION OF THE DRAWINGS

FIG. 1 is a block diagram of one embodiment of an electronic device including an adjusting system.

FIG. 2 is a block diagram of one embodiment of function modules of the adjusting system in FIG. 1.

FIG. 3 is a flowchart of one embodiment of a method of adjusting volume in teleconference.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

In general, the word “module”, as used herein, refers to logic embodied in hardware or firmware, or to a collection of software instructions, written in a programming language. One or more software instructions in the modules may be embedded in firmware, such as in an erasable programmable read only memory (EPROM). The modules described herein may be implemented as either software and/or hardware modules and may be stored in any type of non-transitory computer-readable medium or other storage system. Some non-limiting examples of non-transitory computer-readable media include CDs, DVDs, BLU-RAY, flash memory, and hard disk drives.

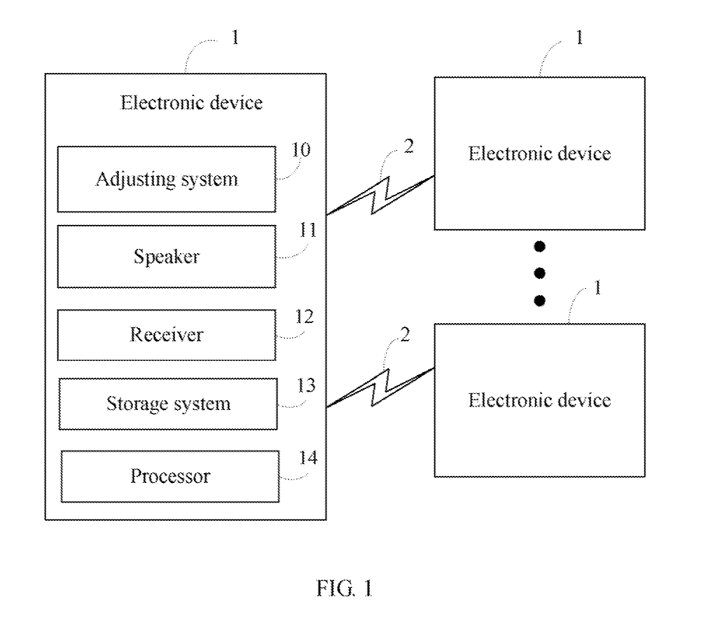

FIG. 1 is a block diagram of one embodiment of an electronic device 1 including an adjusting system 10. In one embodiment, the electronic device 1 may be a computer or a cellular phone, for example. During a teleconference session, there may be many locations communicating with each other. Each location has at least one electronic device 1 for receiving audio from other locations and sending audio to the other locations in teleconference. Each location connects with each other via the Internet or an Intranet. The electronic device 1 further includes a speaker 11, a receiver 12, a storage system 13, and a processor 14. The receiver 12 receives an audio signal from each location. The audio signal from each location includes audio contents, volume parameters, and timbre parameters of each location, for example. The adjusting system 10 adjusts the volume parameters of each location. The speaker 11 plays the audio contents with the adjusted volume parameters.

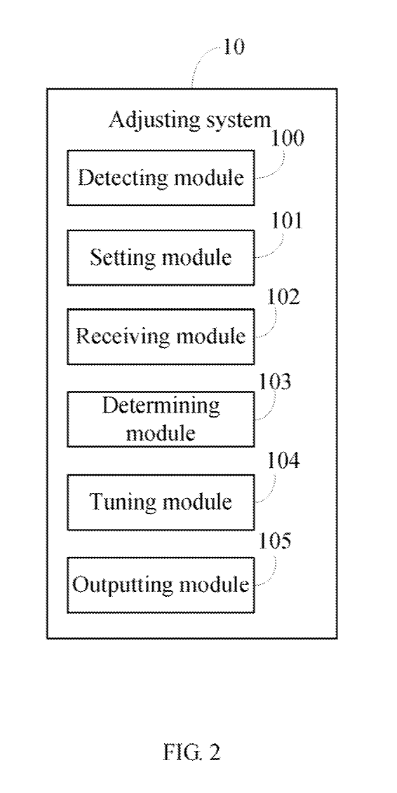

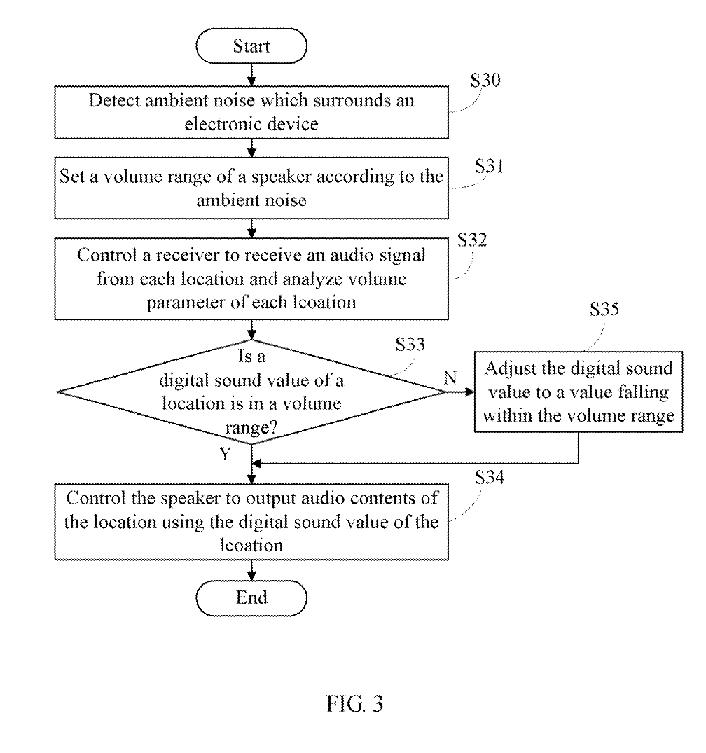

As shown in FIG. 2, the adjusting system 10 includes a plurality of function modules, such as a detecting module 100, a setting module 101, a receiving module 102, a determining module 103, a tuning module 104, and an outputting module 105. The modules 100-105 include computerized code in the form of one or more programs that are stored in the storage system 13. The computerized code includes instructions that are executed by the processor 14, to provide aforementioned functions of the adjusting system 10. Detailed functions of the modules 100-105 are given in reference to FIG. 3.

FIG. 3 is a flowchart of one embodiment of method of adjusting volume in teleconference. Depending on the embodiment, additional steps may be added, others removed, and the ordering of the steps may be changed.

In step S30, the detecting module 100 detects a ambient noise which surrounds the electronic device 1.

In step S31, the setting module 101 sets a volume range of the speaker 11 according to the ambient noise. For example, on condition that the ambient noise is detected as 45 db, and a standard difference between a hearing range of a normal person and the ambient noise is more than 25 db, the setting module sets the volume range of the speaker 11 as more than 70 db.

In step S32, the receiving module 102 controls the receiver 12 to receive the audio signal from each location and analyzes volume parameters of each location. The receiver 12 converts the audio signal to an electrical signal. The receiving module 102 further converts the electrical signal to a digital sound value. The digital sound value is expressed by decibel.

In step S33, the determining module 103 determines whether the digital sound value of a location is in the volume range. If the digital sound value of the location is in the volume range, step S34 is implemented. If the digital sound value of the location is not in the volume range, step S35 is implemented.

In step S34, the outputting module 105 controls the speaker 11 to directly output the audio contents of the location by using the digital sound value of the location.

In step S35, the tuning module 104 adjusts the digital sound value to a value that falls within the volume range, and step S34 is implemented. For example, the tuning module 104 amplifies the analog signal and obtains the digital sound value which falls within the volume range by using a rheostat to adjust amplification of the audio signal.

Although certain disclosed embodiments of the present disclosure have been specifically described, the present disclosure is not to be construed as being limited thereto. Various changes or modifications may be made to the present disclosure without departing from the scope and spirit of the present disclosure.

What is claimed is:

1. An electronic device comprising one or more programs, which comprise instructions that are stored in a non-transitory computer-readable medium, when executed by a processor of the electronic device, performs operations of:
(a) detecting ambient noise which surrounds the electronic device when the electronic device is teleconferencing;
(b) setting a volume range of a speaker of the electronic device according to the ambient noise;
(c) controlling a receiver of the electronic device to receive an audio signal from each attendee location of the teleconference, and analyzing volume parameters of the audio signal from each attendee location;
(d) adjusting a digital sound value of an attendee location in the teleconference when the volume parameter of the attendee location is not in the volume range; and
(e) controlling the speaker to output audio contents of the attendee location when the volume parameters of the attendee location has been adjusted to be in the volume range.

2. The electronic device as claimed in claim 1, wherein the operation (c) comprises:
transferring the audio signal to an electrical signal; and
changing the electrical signal to the digital sound value.

3. The electronic device as claimed in claim 1, wherein the operations further comprise:
controlling the speaker to directly output audio contents of an attendee location when the volume parameter of the attendee location is in the volume range.

4. A method being executed by a processor of an electronic device, comprising steps:
(a) detecting ambient noise which surrounds the electronic device when the electronic device is teleconferencing;
(b) setting a volume range of a speaker of the electronic device according to the ambient noise;
(c) controlling a receiver of the electronic device to receive an audio signal from each attendee location of the teleconference, and analyzing volume parameters of the audio signal from each attendee location;
(d) adjusting a digital sound value of an attendee location in the teleconference when the volume parameter of the attendee location is not in the volume range; and
(e) controlling the speaker to output audio contents of the attendee location when the volume parameters of the attendee location has been adjusted to be in the volume range.

5. The method as claimed in claim 4, wherein the operation (c) comprises:
transferring the audio signal to an electrical signal; and
changing the electrical signal to the digital sound value.

6. The method as claimed in claim 4, wherein the operations further comprise:
controlling the speaker to directly output audio contents of an attendee location when the volume parameter of the attendee location is in the volume range.

7. A non-transitory computer-readable medium having stored thereon instructions that, when executed by a processor of an electronic device, cause the processor to perform operations of:
(a) detecting ambient noise which surrounds the electronic device when the electronic device is teleconferencing;
(b) setting a volume range of a speaker of the electronic device according to the ambient noise;
(c) controlling a receiver of the electronic device to receive an audio signal from each attendee location of the teleconference, and analyzing volume parameters of the audio signal from each attendee location;
(d) adjusting a digital sound value of an attendee location in the teleconference when the volume parameter of the attendee location is not in the volume range; and
(e) controlling the speaker to output audio contents of the attendee location when the volume parameters of the attendee location has been adjusted to be in the volume range.

8. The non-transitory computer-readable medium as claimed in claim 7, wherein the operations comprises:
transferring the audio signal to an electrical signal; and
changing the electrical signal to the digital sound value.

9. The non-transitory computer-readable medium as claimed in claim 7, wherein the operations further comprise:
controlling the speaker to directly output audio contents of an attendee location when the volume parameter of the attendee location is in the volume range.
